(19) United States
(12) Patent Application Publication
(10) Pub. No.: US 2026/0107667 A1
(43) Pub. Date: Apr. 16, 2026

(54) DISPLAY DEVICE

(71) Applicant: LG Display Co., Ltd., Seoul (KR)

(72) Inventors: Nara SHIN, Seoul (KR); Byungjin KIM, Paju-si (KR); Chulho KIM, Incheon (KR)

(73) Assignee: LG Display Co., Ltd., Seoul (KR)

(21) Appl. No.: 19/094,371

(22) Filed: Mar. 28, 2025

(30) Foreign Application Priority Data
Oct. 14, 2024 (KR) 10-2024-0139411

(51) Int. Cl. H10K 59/80; H10K 59/131

(52) U.S. Cl. CPC H10K 59/8792; H10K 59/131

(57) ABSTRACT

A display device includes a substrate having a light-emission area and a non-light-emission area adjacent to the light-emission area, wherein the non-light-emission area includes a circuit area; at least one first low reflective layer disposed on the circuit area of the non-light-emission area of the substrate; a second low reflective layer disposed on the non-light-emission area of the substrate and spaced apart from the first low reflective layer; at least one light blocking layer disposed on an upper surface of the at least one first low reflective layer; and at least one thin-film transistor disposed on the at least one light blocking layer, wherein each of the at least one first low reflective layer and the second low reflective layer is made of a metal oxide.

### CROSS-REFERENCE TO RELATED APPLICATION

This application claims priority from Korean Patent Application No. 10-2024-0139411 filed on October 14, 2024, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device.

### DESCRIPTION OF THE RELATED ART

Display devices are incorporated into various electronic devices, including TVs, mobile phones, laptops, and tablets.

Display devices include organic light-emitting display device (OLED), which generate light through self-emission, and a liquid crystal display device (LCD), which rely on separate light source.

### BRIEF SUMMARY

Light incident from the outside into the display device is reflected from components such as a wiring constituting the display device and then is emitted again through a light exit surface of the display device. The inventors of the present disclosure have recognized that this deteriorates visibility and a contrast ratio of the display device. For this reason, the inventors of the present disclosure have provided various embodiments for reducing reflection of external light. Various embodiments of the present disclosure provide a display device capable of reducing reflection of external light without including a polarizing plate.

Various embodiments of the present disclosure provide a display device capable of simplifying a manufacturing process and reducing a manufacturing cost and a manufacturing time.

Various embodiments of the present disclosure provide a display device that efficiently reduces reflection of external light while preventing generation of parasitic capacitance between signal lines and a low reflective layer.

Various embodiments of the present disclosure provide a display device capable of reducing production energy required for production and thus reducing greenhouse gas emission.

Purposes according to the present disclosure are not limited to the above-mentioned technical benefits. Other benefits and advantages according to the present disclosure that are not mentioned may be understood based on following descriptions, and may be more clearly understood based on embodiments according to the present disclosure. Further, it will be easily understood that the benefits and advantages according to the present disclosure may be realized using means shown in the claims or combinations thereof.

A display device according to embodiments of the present disclosure may include a substrate having a light-emission area and a non-light-emission area adjacent to the light-emission area, wherein the non-light-emission area includes a circuit area; at least one first low reflective layer disposed on the circuit area of the non-light-emission area of the substrate; a second low reflective layer disposed on the non-light-emission area of the substrate and spaced apart from the first low reflective layer; at least one light blocking layer disposed on an upper surface of the at least one first low reflective layer; and at least one thin-film transistor disposed on the at least one light blocking layer, wherein each of the at least one first low reflective layer and the second low reflective layer is made of a metal oxide.

A display device according to embodiments of the present disclosure may include a substrate; a thin-film transistor disposed on the substrate; a signal line disposed on the substrate and electrically connected to the thin-film transistor; a first low reflective layer and a light blocking layer disposed between the substrate and the thin-film transistor so as to be spaced apart from the thin-film transistor; and a second low reflective layer disposed between the substrate and the signal line so as to be spaced apart from the signal line, wherein the first low reflective layer and the second low reflective layer are made of the same material capable of absorbing external light introduced through the substrate.

According to embodiments of the present disclosure, a display device in which reflection of external light may be efficiently reduced by disposing the low reflective layers overlapping the thin-film transistor and the signal lines on the surface of the substrate into which external light is introduced may be provided.

According to embodiments of the present disclosure, the low reflective layer may be disposed only on one surface of the substrate in a wide area without disposing the low reflective layer on each of the lower surfaces of the electrodes of the thin-film transistor and the lower surfaces of the signal lines, such that the manufacturing process of the display device may be simplified, and the manufacturing cost and the manufacturing time may be reduced.

According to embodiments of the present disclosure, even when the low reflective layer is disposed under the signal lines so as to be spaced apart from the signal lines, generation of parasitic capacitance between the signal lines and the low reflective layer may be prevented because the low reflective layer is made of a metal oxide having low electrical conductivity while the low reflective layer efficiently reduces reflection of external light.

According to embodiments of the present disclosure, the manufacturing process of the display device is simplified and the manufacturing time is shortened, so that the production energy required for the production of the display device may be reduced and the emission of greenhouse gas may be reduced.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a plan view schematically illustrating a unit pixel of a display device according to an embodiment of the present disclosure.

FIG. 2 is a plan view schematically illustrating a light blocking layer and a low reflective layer of a display device according to an embodiment of the present disclosure.

FIG. 3 is a cross-sectional view taken along a line I-I′ of FIG. 2;

FIGS. 4 to 10 illustrate a method for manufacturing a display device according to an embodiment of the present disclosure.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to,” or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc., should not be construed such that any aspect or design as described is superior to or advantageous over other aspects or designs.

Further, the term ‘or’ means ‘inclusive or’ rather than ‘exclusive or.’ That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

When a first component or layer is described as “contacting” or “overlapping” a second component or layer, it should be understood that the first component or layer may directly contact or overlap the second component or layer, or a third component or layer may be interposed between the first and second components or layers that may indirectly contact or overlap each other unless otherwise specified.

Hereinafter, various embodiments of the present disclosure will be described in detail with reference to the accompanying drawings.

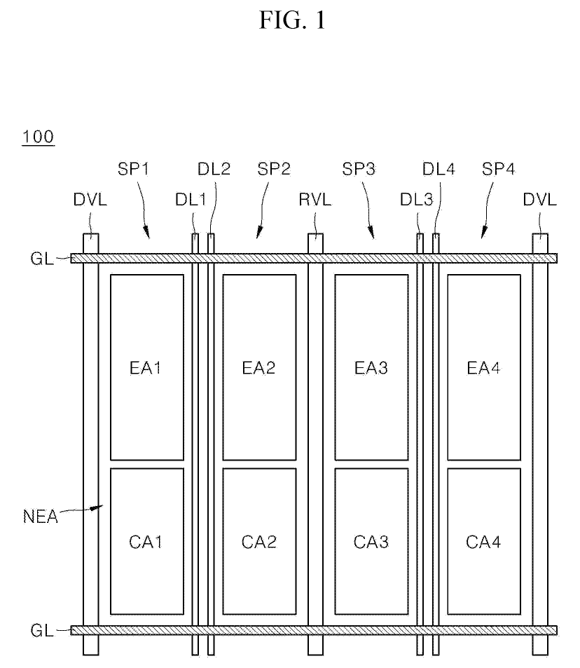

FIG. 1 is a plan view schematically illustrating a unit pixel of a display device according to an embodiment of the present disclosure. The display device according to an embodiment of the present disclosure may be a bottom emission type display device.

Referring to FIG. 1, a display device 100 according to an embodiment of the present disclosure may include unit pixels PX that are repeatedly arranged.

Each of the unit pixels may include a first sub-pixel SP1, a second sub-pixel SP2 adjacent to the first sub-pixel SP1, a third sub-pixel SP3 adjacent to the second sub-pixel SP2, and a fourth sub-pixel SP4 adjacent to the third sub-pixel SP3.

The first sub-pixel SP1 may include a first light-emission area EA1 and a first circuit area CA1 for driving the first light-emission area. The second sub-pixel SP2 may include a second light-emission area EA2 and a second circuit area CA2 for driving the second light-emission area. The third sub-pixel SP3 may include a third light-emission area EA3 and a third circuit area CA3 for driving the third light-emission area. The fourth sub-pixel SP4 may include a fourth light-emission area EA4 and a fourth circuit area CA4 for driving the fourth light-emission area.

An area around each of the first to fourth light-emission areas EA1, EA2, EA3, and EA4 may be a non-light-emission area NEA. Each of the first to fourth circuit areas CA1, CA2, CA3, and CA4 may be a portion of the non-light-emission area NEA. The non-light-emission area NEA may include the first to fourth circuit areas CA1, CA2, CA3, and CA4.

Each of the first to fourth light-emission areas EA1, EA2, EA3, and EA4 may include a light-emitting element that emits white light. Each of the first to fourth circuit areas CA1, CA2, CA3, and CA4 may include at least one thin-film transistor and at least one capacitor.

For example, the first sub-pixel SP1 may be a red sub-pixel, the second sub-pixel SP2 may be a white sub-pixel, the third sub-pixel SP3 may be a blue sub-pixel, and the fourth sub-pixel SP4 may be a green sub-pixel. In this case, a red color filter may be disposed in the first light-emission area EA1, a blue color filter may be disposed in the third light-emission area EA3, and a green color filter may be disposed in the fourth light-emission area EA4. A color filter may not be disposed in the second light-emission area EA2.

The first to fourth light-emission areas EA1, EA2, EA3, and EA4, the first to fourth circuit areas CA1, CA2, CA3, and CA4, and the non-light-emission area NEA may be areas of the substrate.

The display device 100 according to an embodiment of the present disclosure may include first to fourth data lines DL1, DL2, DL3, and DL4 to which a data voltage is supplied, a driving voltage line DVL to which a driving voltage is supplied, a reference voltage line RVL to which a reference voltage is supplied, and a gate line GL which intersects the first to fourth data lines DL1, DL2, DL3, and DL4 and to which a gate voltage is supplied. The driving voltage line DVL and the reference voltage line RVL may also intersect the gate line GL. The first to fourth data lines DL1, DL2, DL3, and DL4, the driving voltage line DVL, the reference voltage line RVL, and the gate line GL may be disposed in the non-light-emission area NEA.

For example, the first to fourth data lines DL1, DL2, DL3, and DL4, the driving voltage line DVL, and the reference voltage line RVL may extend in a first direction, and the gate line GL may extend in a second direction intersecting the first direction.

For example, the first sub-pixel SP1 may be disposed between the driving voltage line DVL and the first data line DL1, and the second sub-pixel SP2 may be disposed between the second data line DL2 and the reference voltage line RVL. For example, the third sub-pixel SP3 may be disposed between the reference voltage line RVL and the third data line DL3, and the fourth sub-pixel SP4 may be disposed between the fourth data line DL2 and the driving voltage line DVL.

Although not shown in FIG. 1, connection lines connecting components of the first to fourth circuit areas CA1, CA2, CA3, and CA4 to the first to fourth data lines DL1, DL2, DL3, and DL4, the driving voltage line DVL, the reference voltage line RVL, and the gate line GL may be further disposed in the non-light-emission area NEA.

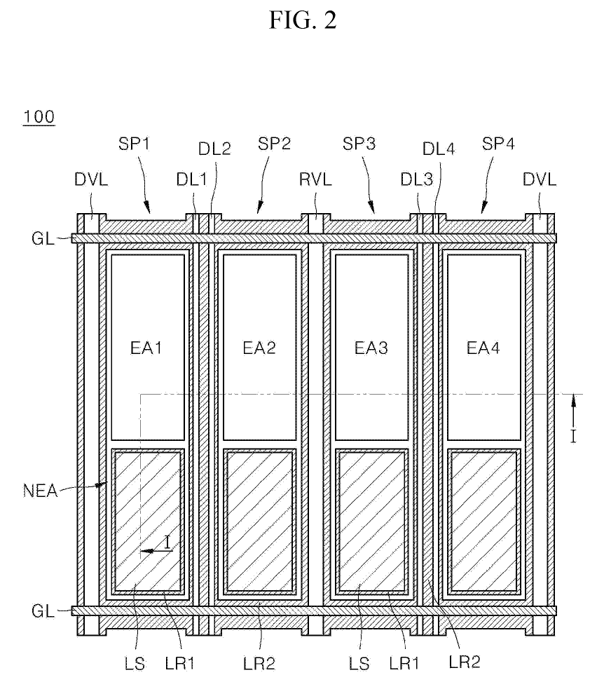

FIG. 2 is a plan view schematically illustrating a light blocking layer and a low reflective layer of a display device according to an embodiment of the present disclosure.

Referring to FIG. 2, a light blocking layer LS may be disposed in each of the first to fourth circuit areas CA1, CA2, CA3, and CA4 of the non-light-emission area NEA. One light blocking layer LS is illustrated in each of the first to fourth circuit areas CA1, CA2, CA3, and CA4. However, embodiments of the present disclosure are not limited thereto. When a plurality of thin-film transistor TFTs are disposed in each of the first to fourth circuit areas CA1, CA2, CA3, and CA4, a plurality of light blocking layers LS may be disposed in each of the first to fourth circuit areas CA1, CA2, CA3, and CA4 in a manner that one light blocking layer LS corresponds to each thin-film transistor TFT, or one light blocking layer LS may be disposed to correspond to all of the plurality of thin-film transistor TFTs. The light blocking layer LS may be disposed under the thin-film transistor TFT, and may prevent external light from being introduced into a semiconductor layer of the thin-film transistor TFT through the substrate to change characteristics of the thin-film transistor TFT.

A first low reflective layer LR1 overlapping the light blocking layer LS and a second low reflective layer LR2 spaced apart from the first low reflective layer LR1 may be further disposed in the non-light-emission area NEA. The second low reflective layer LR2 may overlap the first to fourth data lines DL1, DL2, DL3, and DL4, the driving voltage line DVL, the reference voltage line RVL, and the gate line GL. In addition, the second low reflective layer LR2 may overlap the connection lines connecting the components of the first to fourth circuit areas CA1, CA2, CA3, and CA4 to the first to fourth data lines DL1, DL2, DL3, and DL4, the driving voltage line DVL, the reference voltage line RVL, and the gate line GL. In the present disclosure, the first to fourth data lines DL1, DL2, DL3, and DL4, the driving voltage line DVL, the reference voltage line RVL, the gate line GL, and the connection lines may be collectively referred to as signal lines. As shown in FIG. 2, the second low reflective layer LR2 may be formed integrally in the non-light-emission area NEA. However, embodiments of the present disclosure are not limited thereto. The second low reflective layer LR2 may be formed integrally so as to surround each of the first to fourth light-emitting areas EA1, EA2, EA3, and EA4 and each of the first to fourth circuit areas CA1, CA2, CA3, and CA4 from a plan view (see FIG. 2). However, embodiments of the present disclosure are not limited thereto.

The first low reflective layer LR1 may absorb external light incident through the substrate to reduce reflection of the external light from the light blocking layer LS. The second low reflective layer LR2 may absorb external light incident through the substrate to reduce reflection of the external light from the first to fourth data lines DL1, DL2, DL3, and DL4, the driving voltage line DVL, the reference voltage line RVL, the gate line GL, and the connection line.

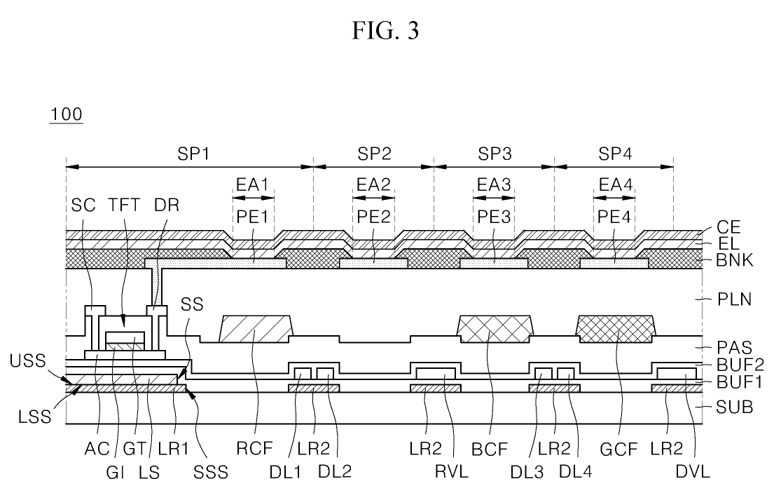

FIG. 3 is a cross-sectional view taken along a line I-I′ of FIG. 2;

Referring to FIG. 3, the first low reflective layer LR1 and the light blocking layer LS may be disposed on the substrate SUB. The first low reflective layer LR1 may be directly disposed on an upper surface of the substrate SUB. However, embodiments of the present disclosure are not limited thereto. For example, an insulating layer may be additionally disposed between the substrate SUB and the first low reflective layer LR1.

The light blocking layer LS may be directly disposed on an upper surface USS of the first low reflective layer LR1. A side surface SSS of the first low reflective layer LR1 may be located further outward than a side surface SS of the light blocking layer LS. An area of the first low reflective layer LR1 may be larger than an area of the light blocking layer LS. Although FIG. 3 illustrates that the first low reflective layer LR1 and the light blocking layer LS are disposed in the first sub-pixel SP1, it is obvious that the first low reflective layer LR1 and the light blocking layer LS are also disposed on the substrate SUB in each of the second to fourth sub-pixels SP2, SP3, and SP4.

The substrate SUB may be a glass substrate or a plastic substrate. The substrate SUB may be made of, for example, an organic insulating material such as polyimide. The substrate SUB may be implemented as, for example, a multi-layer structure in which organic insulating material layers and inorganic insulating material layers are alternately stacked on top of each other.

The light blocking layer LS may have a single-layer or multi-layer structure made of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto. The first low reflective layer LR1 may have a single-layer or multi-layer structure made of a metal oxide such as tungsten oxide (WOx), nickel oxide (NiOx), copper oxide (CuOx), molybdenum oxide (MoOx), or the like. However, embodiments of the present disclosure are not limited thereto.

The first low reflective layer LR1 may be directly disposed on a lower surface LSS of the light blocking layer LS to absorb external light incident through the substrate SUB, thereby reducing reflection of external light from the light blocking layer LS.

The second low reflective layer LR2 may be disposed on the substrate SUB so as to be spaced apart from the first low reflective layer LR1. The second low reflective layer LR2 may be directly disposed on the upper surface of the substrate SUB. However, embodiments of the present disclosure are not limited thereto. For example, an insulating layer may be additionally disposed between the substrate SUB and the second low reflective layer LR2. The second low reflective layer LR2 may be disposed in the non-light-emission area NEA and around each of the first to fourth light-emission areas EA1, EA2, EA3, and EA4. The second low reflective layer LR2 may have a single-layer or multi-layer structure made of a metal oxide such as tungsten oxide (WOx), nickel oxide (NiOx), copper oxide (CuOx), molybdenum oxide (MoOx), or the like. However, embodiments of the present disclosure are not limited thereto. The second low reflective layer LR2 may be made of the same material as that of the first low reflective layer LR1. However, embodiments of the present disclosure are not limited thereto.

A first buffer layer BUF1 covering the first low reflective layer LR1, the light blocking layer LS, and the second low reflective layer LR2 may be disposed on the substrate SUB. The first buffer layer BUF1 may have a single-layer or multi-layer structure made of an inorganic insulating material such as silicon oxide (SiOx), silicon nitride (SiNx), or the like. However, embodiments of the present disclosure are not limited thereto.

The driving voltage line DVL, the first data line DL1, the second data line DL2, the reference voltage line RVL, the third data line DL3, and the fourth data line DL4 may be disposed on the first buffer layer BUF1 so as to be spaced apart from each other. Each of the driving voltage line DVL, the first data line DL1, the second data line DL2, the reference voltage line RVL, the third data line DL3, and the fourth data line DL4 may have a single-layer or multi-layer structure made of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto.

Each of the driving voltage line DVL, the first data line DL1, the second data line DL2, the reference voltage line RVL, the third data line DL3, and the fourth data line DL4 may be disposed to overlap the second low reflective layer LR2. The second low reflective layer LR2 may be disposed under each of the driving voltage line DVL, the first data line DL1, the second data line DL2, the reference voltage line RVL, the third data line DL3, and the fourth data line DL4 and may be spaced apart from each of the driving voltage line DVL, the first data line DL1, the second data line DL2, the reference voltage line RVL, the third data line DL3, and the fourth data line DL4 by a predetermined spacing. The predetermined spacing may correspond to a thickness of the first buffer layer BUF1.

The second low reflective layer LR2 may absorb external light incident through the substrate SUB to reduce reflection of the external light from each of the first to fourth data lines DL1, DL2, DL3, and DL4, the driving voltage line DVL, and the reference voltage line RVL.

A second buffer layer BUF2 may be disposed on the first buffer layer BUF1 so as to cover the driving voltage line DVL, the first data line DL1, the second data line DL2, the reference voltage line RVL, the third data line DL3, and the fourth data line DL4. The second buffer layer BUF2 may have a single-layer or multi-layer structure made of an inorganic insulating material such as silicon oxide (SiOx) or silicon nitride (SiNx). However, embodiments of the present disclosure are not limited thereto.

The thin-film transistor TFT may be disposed on the second buffer layer BUF2. An active layer AC may be disposed on the second buff layer BUF2. The active layer AC may be made of a polycrystalline semiconductor or an oxide semiconductor. The active layer AC may be referred to as a semiconductor layer.

A gate electrode GT may be disposed on the active layer AC. The gate electrode GT may have a single-layer or multi-layer structure made of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto. Although not shown in FIG. 3, a gate line GL (see FIG. 2) may be disposed in the same layer as a layer of the gate electrode GT. The gate line GL may be made of the same material as that of the gate electrode. However, embodiments of the present disclosure are not limited thereto. The second low reflective layer LR2 may be disposed under the gate line GL and at a position overlapping the gate line GL. The second low reflective layer LR2 may absorb external light incident through the substrate SUB, thereby reducing reflection of the external light from the gate line GL.

A gate insulating layer GI may be disposed between the gate electrode GT and the active layer AC. The gate insulating layer GI may have the same area as that of the gate electrode GT. However, embodiments of the present disclosure are not limited thereto. For example, the gate insulating layer GI may also be disposed on the second buffer layer BUF2. The gate insulating layer GI may have a single-layer or multi-layer structure made of an inorganic insulating material such as silicon oxide (SiOx) or silicon nitride (SiNx). However, embodiments of the present disclosure are not limited thereto.

A passivation layer PAS may be disposed on the gate electrode GT. The passivation layer PAS may be disposed on the second buffer layer BUF2 so as to cover the gate electrode GT. The passivation layer PAS may have a single-layer or multi-layer structure made of an inorganic insulating material such as silicon oxide (SiOx) or silicon nitride (SiNx). However, embodiments of the present disclosure are not limited thereto.

A source electrode SC and a drain electrode DR may be disposed on the passivation layer PAS. The source electrode SC and the drain electrode DR may extend through the passivation layer PAS so as to be electrically connected to the active layer AC. Each of the source electrode SC and the drain electrode DR may have a single-layer or multi-layer structure made of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto. The source electrode SC and the drain electrode DR may be electrically connected to the data lines DL1, DL2, DL3, and DL4, the driving voltage line DVL, the reference voltage line RVL, etc., via connection lines. The second low reflective layer LR2 may be disposed under the connection lines and spaced apart from the connection lines by a predetermined spacing.

Even when the second low reflective layer LR2 is disposed under each of the signal lines including the first to fourth data lines DL1, DL2, DL3, and DL4, the driving voltage line DVL, the reference voltage line RVL, the gate line GL, and the connection lines CNL and is spaced from each of the signal lines by the predetermined spacing, generation of parasitic capacitance between each of the signal lines and the second low reflective layer may be prevented because the second low reflective layer LR2 is made of a metal oxide having low electrical conductivity, while the second low reflective layer LR2 efficiently reduces reflection of the external light.

Color filters RCF, BCF, and GCF may be disposed on the passivation layer PAS. The first color filter RCF may be disposed in the first sub-pixel SP1, the second color filter BCF may be disposed in the third sub-pixel SP3, and the third color filter GCF may be disposed in the fourth sub-pixel SP4. For example, the first color filter RCF may be a red color filter, the second color filter BCF may be a blue color filter, and the third color filter GCF may be a green color filter. A color filter may not be disposed in the second sub-pixel SP2.

A planarization layer PLN may be disposed on the passivation layer PAS so as to cover the first, second, and third color filters RCF, BCF, and GCF in order to planarize a step caused due to the thin-film transistor TFT and the first, second, and third color filters RCF, BCF, and GCF. The planarization layer PLN may be referred to as an overcoat layer. The planarization layer PLN may be disposed to planarize the step caused by the thin-film transistor TFT and the first, second, and third color filters RCF, BCF, and GCF. The planarization layer PLN may be made of an organic insulating material such as polyimide or acrylic resin.

First to fourth pixel electrodes PE1, PE2, PE3, and PE4 may be disposed on the planarization layer PLN. The first pixel electrode PE1 may be disposed in the first sub-pixel SP1, the second pixel electrode PE2 may be disposed in the second sub-pixel SP2, the third pixel electrode PE3 may be disposed in the third sub-pixel SP3, and the fourth pixel electrode PE4 may be disposed in the fourth sub-pixel SP4. Each of the first to fourth pixel electrodes PE1, PE2, PE3, and PE4 may be made of a transparent conductive material.

A bank layer BNK may be disposed on the planarization layer PLN so as to cover an edge of an upper surface of each of the first to fourth pixel electrodes PE1, PE2, PE3, and PE4. Each of the first to fourth light-emission areas EA1, EA2, EA3, and EA4 may correspond to an area of each of the first to fourth pixel electrodes PE1, PE2, PE3, and PE4 not covered with the bank layer BNK so as to be exposed.

A light-emitting layer EL may be disposed on the first to fourth pixel electrodes PE1, PE2, PE3, and PE4. For example, the light-emitting layer EL may emit white light. The light-emitting layer EL may be commonly disposed across the first to fourth sub-pixels SP1, SP2, SP3, and SP4.

A common electrode CE may be disposed on the light-light-emitting layer EL. The common electrode CE may be commonly disposed across the first to fourth sub-pixels SP1, SP2, SP3, and SP4. The common electrode CE may be made of a reflective conductive material. The white light generated from the light-emitting layer EL may travel through the first to fourth pixel electrodes PE1, PE2, PE3, and PE4 and may travel toward the substrate SUB, or may be reflected from the common electrode CE and then may travel toward the substrate SUB.

The white light generated from the light-emitting layer EL of the first light-emission area EA1 may be converted into, for example, red light through the first color filter RCF and then emitted to the outside. The white light generated in the light-emitting layer EL of the third light-emission area EA3 may be converted into, for example, blue light through the second color filter BCF and then emitted to the outside. The white light generated in the light-emitting layer EL of the fourth light-emission area EA4 may be converted into, for example, green light through the fourth color filter CF4 and then emitted to the outside. The white light generated from the light-emitting layer EL of the second light-emission area EA2 may be emitted to the outside through the planarization layer PLN.

An encapsulation layer for suppressing moisture penetration may be further disposed on the common electrode CE. The encapsulation layer may include a first inorganic encapsulation layer, an organic encapsulation layer, and a second inorganic encapsulation layer that are sequentially stacked. Each of the first inorganic encapsulation layer and the second inorganic encapsulation layer may be made of an inorganic insulating material such as silicon oxide or silicon nitride. The organic encapsulation layer may be made of an organic insulating material such as acryl resin, epoxy resin, phenolic resin, polyamide resin, and polyimide resin.

In addition, a touch sensor and an optical film may be further disposed on the encapsulation layer.

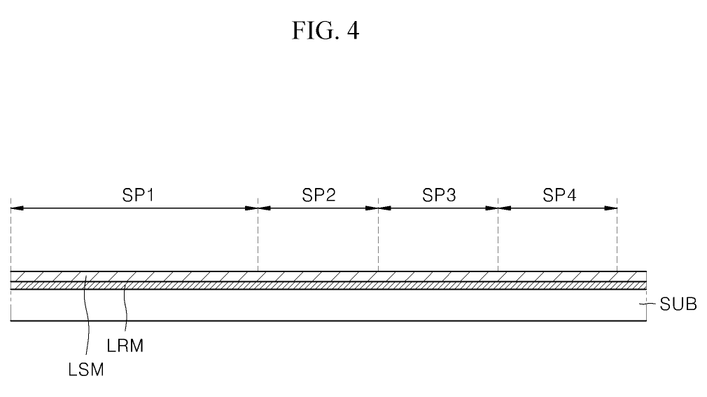

FIGS. 4 to 10 illustrate a method for manufacturing a display device according to an embodiment of the present disclosure. Specifically, FIGS. 4 to 10 illustrate a method of forming the light blocking layer LS, the first low reflective layer LR1, and the second low reflective layer LR2 of FIG. 3.

Referring to FIG. 4, a low reflective material layer LRM and a light blocking material layer LSM may be sequentially stacked on the substrate SUB.

The low reflective material layer LRM may have a single-layer or multi-layer structure made of a metal oxide such as tungsten oxide (WOx), nickel oxide (NiOx), copper oxide (CuOx), molybdenum oxide (MoOx), or the like. However, embodiments of the present disclosure are not limited thereto. The light blocking material layer LSM may have a single-layer or multi-layer structure including one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto.

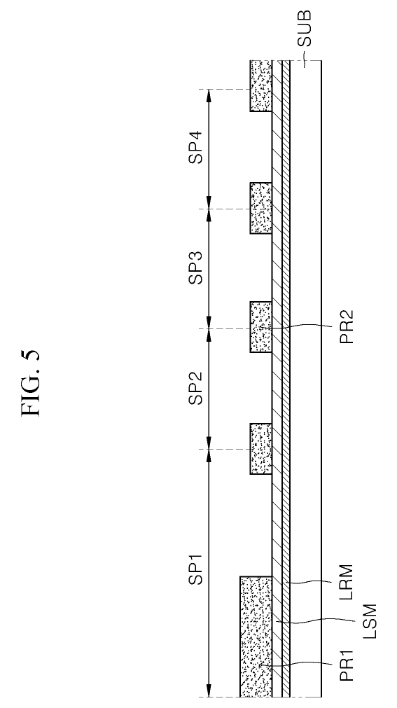

Referring to FIG. 5, a first photoresist pattern PR1 and a second photoresist pattern PR2 having different thicknesses may be formed on the light blocking material layer LSM by coating a photoresist on the light blocking material layer LSM and then performing exposure using a halftone mask. A thickness of the first photoresist pattern PR1 may be greater than a thickness of the second photoresist pattern PR2.

The first photoresist pattern PR1 and the second photoresist pattern PR2 may be formed in the non-light-emission area NEA of the substrate SUB so as to be spaced apart from each other. The first photoresist pattern PR1 may be formed in a circuit area of each of the first to fourth sub-pixels SP1, SP2, SP3, and SP4. The second photoresist pattern PR2 may be formed integrally so as to surround a light-emitting area and a circuit area of each of the first to fourth sub-pixels SP1, SP2, SP3, and SP4. A portion of the second photoresist pattern PR2 may be formed in a boundary area between adjacent ones of the first to fourth sub-pixels SP1, SP2, SP3, and SP4. The first photoresist pattern PR1 may be formed at a position where the first low reflective layer LR1 is to be formed in a subsequent process, and the second photoresist pattern PR2 may be formed at a position where the second low reflective layer LR2 is to be formed in a subsequent process.

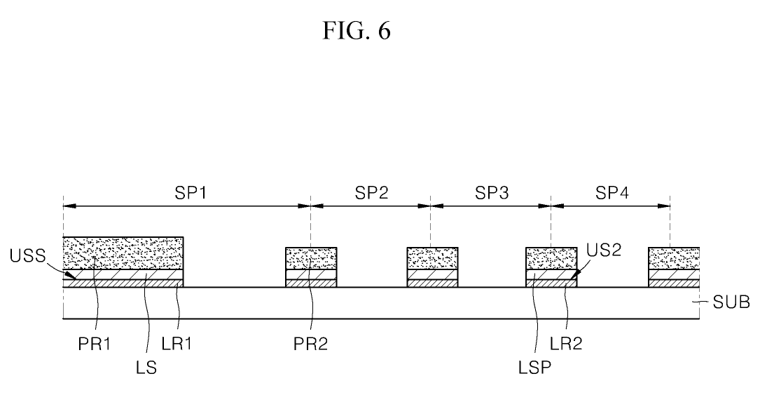

Referring to FIG. 6, the light blocking material layer LSM and the low reflective material layer LRM may be etched using the first photoresist pattern PR1 and the second photoresist pattern PR2 as etch masks. For example, the light blocking material layer LSM and the low reflective material layer LRM may be etched in a wet etching process. At this time, the light blocking layer LS, the light blocking material pattern LSP, the first low reflective layer LR1, and the second low reflective layer LR2 may be patterned on the substrate SUB. The light blocking layer LS may be formed on the upper surface USS of the first low reflective layer LR1, and a light blocking material pattern LSP may be formed on the upper surface US2 of the second low reflective layer LR2.

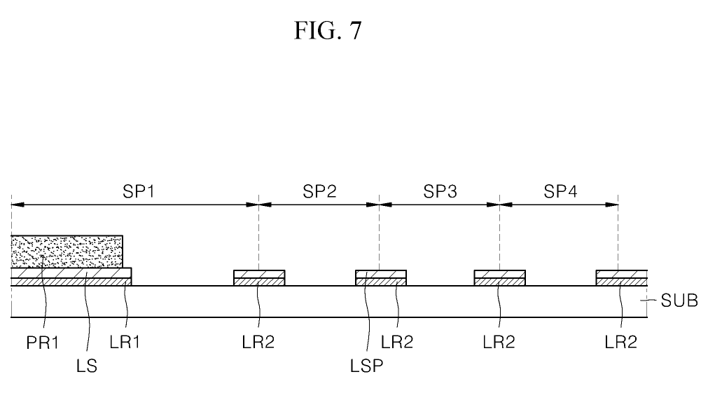

Referring to FIG. 7, the second photoresist pattern PR2 may be removed by an ashing process. Since the thickness of the second photoresist pattern PR2 is smaller than the thickness of the first photoresist pattern PR1, a portion of the first photoresist pattern PR1 may remain even when the second photoresist pattern PR2 is entirely removed. At this time, the thickness of the first photoresist pattern PR1 may be reduced, and a width of the first photoresist pattern PR1 may also be reduced. Accordingly, an edge of the light blocking layer LS positioned under the first photoresist pattern PR1 may be exposed.

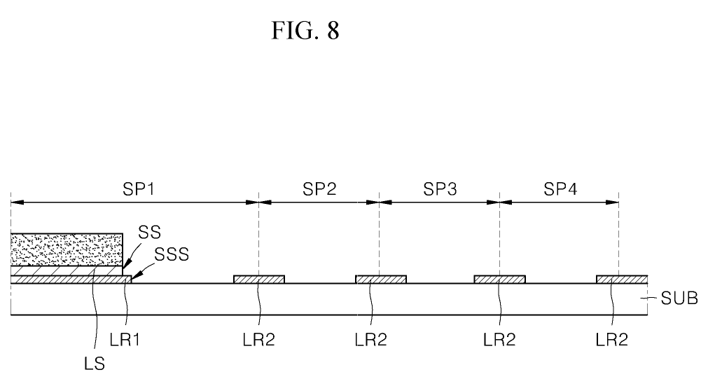

Referring to FIG. 8, the light blocking material pattern LSP on the second low reflective layer LR2 may be removed using the remaining portion of the first photoresist pattern PR1 as an etch mask. For example, the light blocking material pattern LSP may be etched in a wet etching process. At this time, the edge of the light blocking layer LS exposed by the first photoresist pattern PR1 may also be etched. Thus, a side surface SS of the light blocking layer LS may be positioned further inward that a side surface SSS of the first low reflective layer LR1. The area of the light blocking layer LS may be smaller than the area of the first low reflective layer LR1.

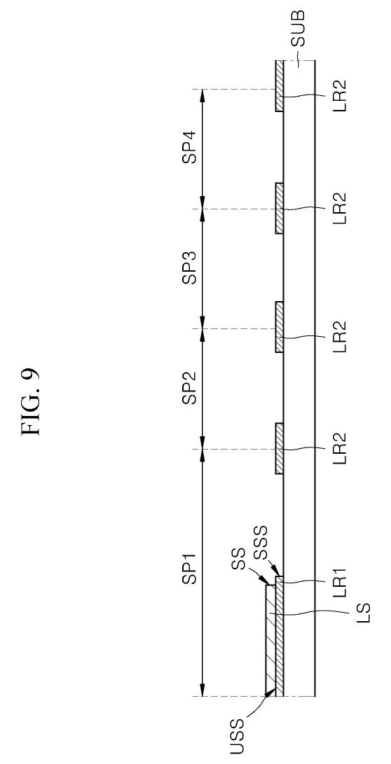

Referring to FIG. 9, the first photoresist pattern PR1 may be entirely removed in a strip process. Accordingly, the first low reflective layer LR1, the second low reflective layer LR2, and the light blocking layer LS disposed on the upper surface USS of the first low reflective layer LR1 may be formed on the substrate SUB.

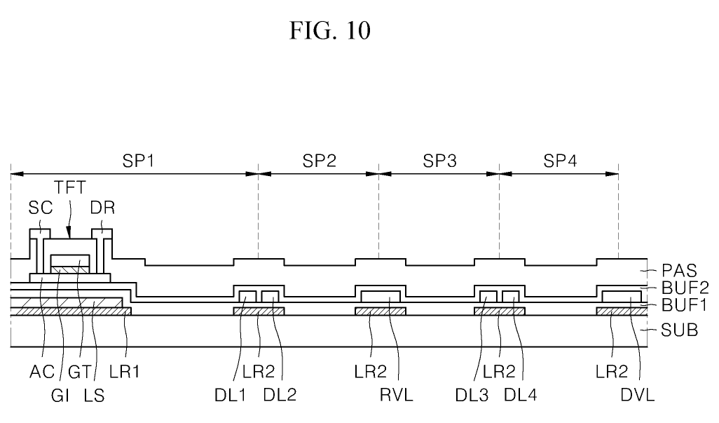

Referring to FIG. 10, the first buffer layer BUF1 may be formed on the substrate SUB on which the first low reflective layer LR1, the second low reflective layer LR2, and the light blocking layer LS have been formed. The first buffer layer BUF1 may cover the light blocking layer LS and the second low reflective layer LR2.

The driving voltage line DVL, the first data line DL1, the second data line DL2, the reference voltage line RVL, the third data line DL3, and the fourth data line DL4 may be formed on the first buffer layer BUF1 so as to overlap the second low reflective layer LR2.

The second buffer layer BUF2 may be formed on the first buffer layer BUF1 so as to cover the driving voltage line DVL, the first data line DL1, the second data line DL2, the reference voltage line RVL, the third data line DL3, and the fourth data line DL4.

The thin-film transistor TFT may be formed on the second buffer layer BUF2 so as to overlap the light blocking layer LS. The active layer AC of the thin-film transistor TFT may be formed on the second buffer layer BUF2 so as to overlap the light blocking layer LS. In addition, the gate electrode GT and the gate insulating layer GI may be formed on the active layer AC. While the gate electrode GT is formed, the gate line may be formed together.

The passivation layer PAS covering the gate electrode GT may be formed on the substrate SUB. The source electrode SC and the drain electrode DR may be formed on the passivation layer PAS, and may extend through the passivation layer PAS so as to be connected to the active layer AC.

Thereafter, the color filters RCF, BCF, and GCF, the planarization layer PLN, the pixel electrodes PE1, PE2, PE3, and PE4, the bank layer BNK, the light-emitting layer EL, and the common electrode CE may be formed on the passivation layer PAS (see FIG. 3).

Although the display device including the four sub-pixels SP1, SP2, SP3, and SP4, for example, the red, white, blue, and green sub-pixels has been described above, the embodiments of the present disclosure are not limited thereto. It is obvious that the light blocking layer LS, the first low reflective layer LR1, and the second low reflective layer LR2 according to an embodiment of the present disclosure may be equally or similarly applied to a display device including three sub-pixels, for example, red, blue, and green sub-pixels.

The display device according to various aspects and embodiments of the present disclosure may be described as follows.

A first aspect of the present disclosure provides a display device comprising: a substrate having a light-emission area and a non-light-emission area adjacent to the light-emission area, wherein the non-light-emission area includes a circuit area; at least one first low reflective layer disposed on the circuit area of the non-light-emission area of the substrate; a second low reflective layer disposed on the non-light-emission area of the substrate and spaced apart from the first low reflective layer; at least one light blocking layer disposed on an upper surface of the at least one first low reflective layer; and at least one thin-film transistor disposed on the at least one light blocking layer, wherein each of the at least one first low reflective layer and the second low reflective layer is made of a metal oxide.

In accordance with some embodiments of the first aspect of the present disclosure, a side surface of the at least one first low reflective layer is positioned further outward than a side surface of the at least one light blocking layer.

In accordance with some embodiments of the first aspect of the present disclosure, the second low reflective layer surrounds the light-emission area and the circuit area and is formed integrally.

In accordance with some embodiments of the first aspect of the present disclosure, the display device further comprises: a first buffer layer covering the at least one light blocking layer and the second low reflective layer; and at least one signal line disposed on the first buffer layer so as to overlap the second low reflective layer.

In accordance with some embodiments of the first aspect of the present disclosure, the at least one signal line includes a data line, a driving voltage line, a reference voltage line, and a gate line.

In accordance with some embodiments of the first aspect of the present disclosure, the display device further comprises a second buffer layer covering the at least one signal line, wherein the at least one thin-film transistor is disposed on the second buffer layer so as to overlap the at least one light blocking layer.

In accordance with some embodiments of the first aspect of the present disclosure, each of the first low reflective layer and the second low reflective layer has a single-layer or multi-layer structure including at least one of tungsten oxide, nickel oxide, copper oxide, and molybdenum oxide.

In accordance with some embodiments of the first aspect of the present disclosure, the at least one first low reflective layer and the second low reflective layer are directly disposed on one surface of the substrate through which external light is introduced.

A first aspect of the present disclosure provides a display device comprising: a substrate; a thin-film transistor disposed on the substrate; a signal line disposed on the substrate and electrically connected to the thin-film transistor; a first low reflective layer and a light blocking layer disposed between the substrate and the thin-film transistor so as to be spaced apart from the thin-film transistor; and a second low reflective layer disposed between the substrate and the signal line so as to be spaced apart from the signal line, wherein the first low reflective layer and the second low reflective layer are made of the same material capable of absorbing external light introduced through the substrate.

In accordance with some embodiments of the second aspect of the present disclosure, the first low reflective layer and the second low reflective layer are directly disposed on one surface of the substrate through which the external light is introduced.

In accordance with some embodiments of the second aspect of the present disclosure, an area in a plan view of the first low reflective layer is larger than an area in a plan view of the light blocking layer.

In accordance with some embodiments of the second aspect of the present disclosure, the second low reflective layer is spaced apart from the first low reflective layer.

In accordance with some embodiments of the second aspect of the present disclosure, the signal line includes a data line, a driving voltage line, a reference voltage line, and a gate line.

In accordance with some embodiments of the second aspect of the present disclosure, each of the first low reflective layer and the second low reflective layer has a single-layer or multi-layer structure including a metal oxide including at least one of tungsten oxide, nickel oxide, copper oxide, and molybdenum oxide.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate having a light-emission area and a non-light-emission area adjacent to the light-emission area, the non-light-emission area including a circuit area;
at least one first reflective layer on the circuit area of the non-light-emission area of the substrate;
a second reflective layer on the non-light-emission area of the substrate and spaced apart from the first reflective layer;
at least one light blocking layer on an upper surface of the at least one first reflective layer; and
at least one thin-film transistor on the at least one light blocking layer,
wherein each of the at least one first reflective layer and the second reflective layer is made of a metal oxide.

2. The display device of claim 1, wherein a side surface of the at least one first reflective layer is positioned further outward than a side surface of the at least one light blocking layer.

3. The display device of claim 1, wherein the second reflective layer is formed integrally and surrounds the light-emission area and the circuit area from a plan view.

4. The display device of claim 1, further comprising:
a first buffer layer covering the at least one light blocking layer and the second reflective layer; and
at least one signal line on the first buffer layer so as to overlap the second reflective layer.

5. The display device of claim 4, wherein the at least one signal line includes a data line, a driving voltage line, a reference voltage line, and a gate line.

6. The display device of claim 4, further comprising:
a second buffer layer covering the at least one signal line,
wherein the at least one thin-film transistor is on the second buffer layer so as to overlap the at least one light blocking layer.

7. The display device of claim 1, wherein each of the first reflective layer and the second reflective layer has a single-layer or multi-layer structure including at least one of tungsten oxide, nickel oxide, copper oxide, and molybdenum oxide.

8. The display device of claim 1, wherein the at least one first reflective layer and the second reflective layer are directly on one surface of the substrate through which external light is introduced.

9. A display device comprising:
a substrate;
a thin-film transistor on the substrate;
a signal line on the substrate and electrically connected to the thin-film transistor;
a first reflective layer and a light blocking layer between the substrate and the thin-film transistor so as to be spaced apart from the thin-film transistor; and
a second reflective layer between the substrate and the signal line so as to be spaced apart from the signal line,
wherein the first reflective layer and the second reflective layer are made of a same material configured to absorb external light introduced through the substrate.

10. The display device of claim 9, wherein the first reflective layer and the second reflective layer are directly on one surface of the substrate through which the external light is introduced.

11. The display device of claim 9, wherein an area of the first reflective layer is larger than an area of the light blocking layer.

12. The display device of claim 9, wherein the second reflective layer is spaced apart from the first reflective layer.

13. The display device of claim 9, wherein the signal line includes a data line, a driving voltage line, a reference voltage line, and a gate line.

14. The display device of claim 9, wherein each of the first reflective layer and the second reflective layer has a single-layer or multi-layer structure including a metal oxide including at least one of tungsten oxide, nickel oxide, copper oxide, and molybdenum oxide.
